(19) United States
(12) Patent Application Publication
(10) Pub. No.: US 2007/0128875 A1
(43) Pub. Date: Jun. 7, 2007

(54) Dry etch release method for micro-electro-mechanical systems (MEMS)

(76) Inventor: Jeffrey R. Jessing, Boise, ID (US)

Correspondence Address: PEDERSEN & COMPANY, PLLC, P.O. BOX 2666, BOISE, ID, 83701, US

(21) Appl. No.: 11/293,034

(22) Filed: Dec. 2, 2005

(51) Int. Cl. H01L 21/30; H01L 21/00; H01L 21/302; H01L 21/461

(52) U.S. Cl. 438/706; 438/712; 438/689; 438/735; 438/734; 438/462; 438/458

(57) ABSTRACT

The present invention provides a means for releasing semiconductor, micromachined and/or Micro-Electro-Mechanical Systems (MEMS) parts from a substrate. Semiconductor, micromachined or MEMS components built at the wafer level must be separated after fabrication. Through novel application of Deep Reactive Ion Etching (DRIE) or Bosch etching to etch through the substrate, full or partial separation is achieved. The formation of fine edges and ultra-linear sidewalls can be achieved, and no residues remain as a result of the process. Alternative embodiments of the present invention allow subsequent micromachining or other process steps to be accomplished, in bulk, to the bottom of the die. Other alternative embodiments involve fabrication of horizontal or vertical attachment webs or tabs between die by partial through-etching or by photo-resist patterning sections between the die prior to a dry-etch, leaving the webs or tabs.

Activities related to this non-provisional patent application were conducted with funding under NSF EPSCOR #NEC6105JESS.

### BACKGROUND OF THE INVENTION

1. Field of the Invention

This invention relates generally to fabrication of micro-electro-mechanical systems (MEMS), and more particularly to the method of dry-etched release of micromachined and/or integrated circuit parts.

2. Related Art

The present invention has been shown to provide a superior method with multiple embodiments for releasing and/or separating micromachined parts and/or integrated circuits from adjacent materials that are fabricated on thin-film substrates such as silicon wafers. The inventors have found no other similar methods either in the art or commercially that offer the advantages of being a reproducible, damage-free and inexpensive way of releasing or separating of individual parts.

De Juan, Jr. et al, U.S. Pat. No. 5,317,938, discloses a method of making a microsurgical cutter from a flat planar substrate. In this method of substrate is etched isotropically both from the top surface and the bottom surface so that the angled etch trenches of these surfaces meet at the cutter edge portion.

Mehregany, U.S. Pat. No. 5,579,583, discloses a cutting edge in a single-crystal silicon wafer from the intersection of the (100) plane and the (111) plane, resulting in a blade having an angle of 54.74 degrees. For this cutting edge, then, it is defined at any point along the edge by the intersection of two crystal planes. In some embodiments, a sharp tip may be formed of an intersection of several crystal planes.

U.S. Pat. No. 5,842,387 to Marcus, et al, discloses making sharp knife blades from wafers of silicon. The method of this patent includes creating an elongated ridge having a flat top covered by an enchant mask. Then, the mask is undercut to shape the ridge side walls so that they inwardly converge towards the ridge tip. Then the mask is removed and a sharp ridge apex is provided by oxide forming and stripping.

U.S. Pat. No. 6,399,516 to Avon describes a method for producing silicon elements by etching first vertically to an insulating layer and then laterally along the surface of the insulating layer. This patent also describes a method of etching an angled trench in a silicon layer.

U.S. Pat. No. 6,429,033 to Gee, et al. describes a method for fabricating a mirror array from a silicon on insulator substrate structure. According to the method a mirror device and a torsion bar structure are formed using a deep reactive ion etch, and removed from the insulator material.

U.S. Pat. No. 6,544,898 to Polson et al. describes a method of etching a release trench in a handle layer. Then, a cooperating release trench is etched in a device layer separated from the handle layer by an etch-stop layer. The device layer is then separated from the handle layer.

Fleming, U.S. Pat. No. 6,615,496, discloses a cutting blade defined by the intersection of {211} crystalline planes with {111} crystalline planes of silicon, resulting in a cutting blade which has a cutting angle of 19.5 degrees.

U.S. Pat. No. 6,664,126 to Devoe, et al. describes a method for MEMS manufacture by deep reactive ion etching (DRIE) of silicon on insulator material, followed by thermal oxidation of the trenches opened during the DRIE etching.

U.S. Pat. No. 6,706,549 to Okojie describes a method for an etch-through of an aperture in a substrate by DRIE. However, in this patent, no release of a MEMS from the substrate is disclosed.

U.S. Pat. No. 6,756,247 to Davis, et al. describes a method of creating a single mask MEMS structure by deep reactive ion etching on the top surface of a wafer. Thereafter, a bottom surface etch cooperates with trenches formed in the MEMS structure to provide through trenches which releases the MEMS.

### SUMMARY OF THE INVENTION

The present invention involves refined methodology for fabrication of semiconductor, micromachined or Micro-Electro-Mechanical Systems (MEMS) structures or devices which are typically fabricated on semiconductor substrates, such as silicon wafers. Micromachined or MEMS structures may be integrated with electrical circuits on a common substrate, and are found in numerous applications across industries including medical devices such as blades, sensors, and other precision instruments. Exemplary micromachined or MEMS applications include optical controls, sensors, and biomedical devices, for example.

Semiconductor, micromachined or MEMS components are typically built at the wafer level and must be separated from the wafer after fabrication. This process is referred to as “die release.” The term “die” is typically defined as the piece of wafer containing a semiconductor, micromachined or MEMS structure. Typically a single wafer contains tens to hundreds of die.

To achieve release of semiconductor, micromachined or MEMS die, conventional methods such as sawing and laser scribing induce significant damage and defects that can predispose the released parts to fail both mechanically and electrically. For instance, monocrystalline silicon parts will exhibit severe dislocations along crystalline boundaries from sawing and laser scribing. Dicing by-products such as silicon dust also can render parts non-functional or less functional. These by-products are troublesome in integrated circuit manufacture, but are particularly problematic when separating MEMS structures.

A major aspect of this patent is the formation of straight edges and ultra-linear sidewalls, for example, for medical devices. Medical devices, like scapels, for example, are traditionally ground using metal, alloys or diamond materials. This process often results in jagged edges, especially on a microscopic level. Also, this grinding process results in non-uniformity among different devices, and higher cost since devices must be manufactured in serial fashion. In contrast, the benefits of batch manufacturing medical devices, for example, and specifically the benefits from using the Deep Reactive Ion Etch or Bosch Process according to the method of this invention to yield the die release, include lower cost devices, ultra-linear edges, and higher degree of uniformity among devices.

The etch release method of the present invention does not generate undesirable or overly stressed die material by-products. Through novel application of Deep Reactive Ion Etching (DRIE) or Bosch etching, both being well-known dry-etch processes in the semiconductor and MEMS industries, the formation of straight edges and ultra-linear sidewalls can be achieved. These straight edges and sidewalls facilitate the clean separation of semiconductor, micromachined or MEMS die.

In achieving the methods of the present invention, the semiconductor, micromachined or MEMS die to be released are protected from the dry-etching process by the application of photo-resistive patterning material. By patterning a photo-resistive material over the die to be separated, and subsequently using a dry-etch process, troughs with ultra-linear sidewalls are created between the patterned areas to release the die.

In one aspect of the present invention, troughs are not dry-etched completely through, but only mostly through, thereby leaving a thin, horizontal tab of substrate on the bottom of the wafer. Then, a polymer, oxide or other suitable material is filled into the trough areas by means of chemical vapor deposition, or by spin coating, for example, according to conventional techniques. This filled-in material serves to bind the die together so that when the bottom substrate layer is removed by subsequent polishing or dry-etching from the backside, die are kept together. Thereby, subsequent micromachining or other process steps can be accomplished, in bulk, to the newly exposed bottom of the die before release. Finally, by removing the filler material, the die are fully separated.

Another alternate aspect of the present invention is a method of creating vertical attachment tabs or webs between die by photo-resist patterning thin sections between the die prior to the dry-etch separation step. By creating these thin, vertical attachment tabs or webs between die, it allows die to remain attached to one another, but able to be broken or taken apart during a subsequent process step. This aspect also facilitates bulk micromachining or other process steps to be accomplished prior to final separation.

These and other embodiments, aspects, advantages and features of the present invention will be set forth in part in the description, and in part will come to those skilled in the art by reference to the following description of the invention and referenced drawings, or by practice of the invention.

### BRIEF DESCRIPTION OF THE DRAWINGS

FIG. 1 is a schematic, side sectional sequence of three (3) views depicting a through-etch according to one method of the present invention.

FIG. 2 is a schematic, perspective sequence of two (2) views of an alternate method of the present invention, depicting creation of horizontal interconnecting tabs or webs at the bottom of the wafer between MEMS by means of a partial through-etch.

FIG. 3 is a schematic, perspective sequence of two (2) views of another alternate method of the present invention, depicting creation of vertical interconnecting webs between MEMS.

FIG. 4 is a schematic, perspective sequence of two (2) views of an alternate method of the present invention, depicting using a filler material between individual die after a partial through-etch according to the method of FIG. 2.

FIG. 5 is a schematic, perspective view of one embodiment of the present invention, depicting the partial separation of odd-shaped die.

### DETAILED DESCRIPTION OF THE INVENTION

In creating semiconductor, micromachined or MEMS die, the process of dry-etching is commonly used. Several popular processes are known in the industry, such as the Bosch etching and Deep Reactive Ion Etching (DRIE) processes. In the present invention, these processes are applied in a number of novel ways, as to provide for the separation of die from one-another. It should be noted that, in the Figures, the depictions are of typical wafers, sectioned in the front along die boundaries and the sides and back as rough cutaways. In reality, entire wafers are constructed yielding a two-dimensional matrix of semiconductor, micromachined or MEMS die which can be fabricated and separated with the methods herein described.

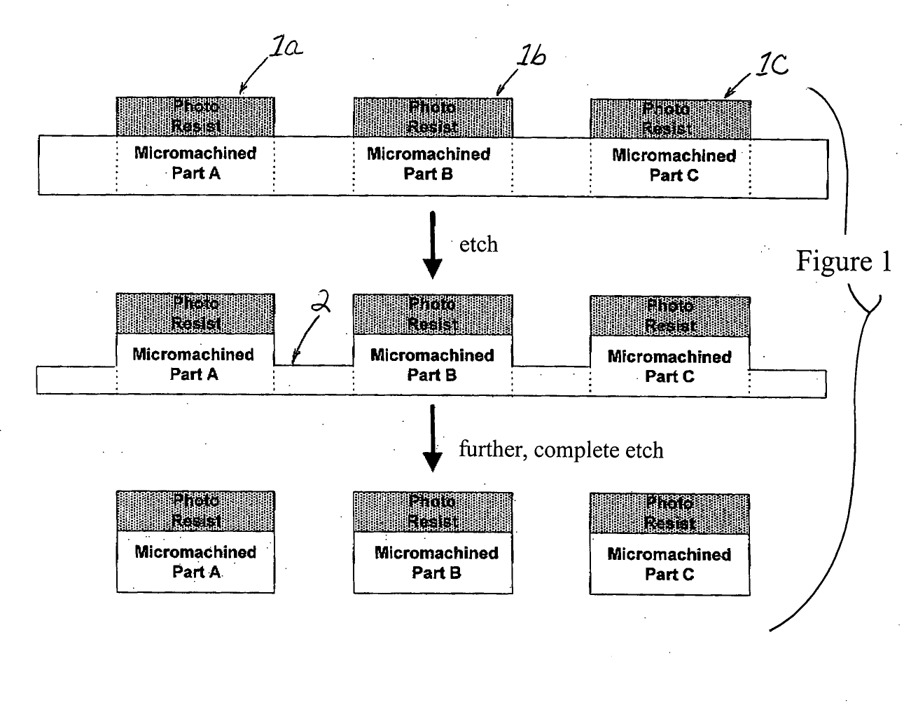

Referring to FIG. 1, there is depicted a schematic, side sectional sequence of three (3) views of the through-etch method of the present invention. In this figure, three representative micromachined die A, B, and C are shown in the top-most section view coated with photo-resist layer 1a, 1b and 1c, which are selectively created through photo-patterning. In the middle section view, the vertical troughs from etching are shown partially formed, and in the bottom section view the completed, etched-through troughs are shown and the die are separated.

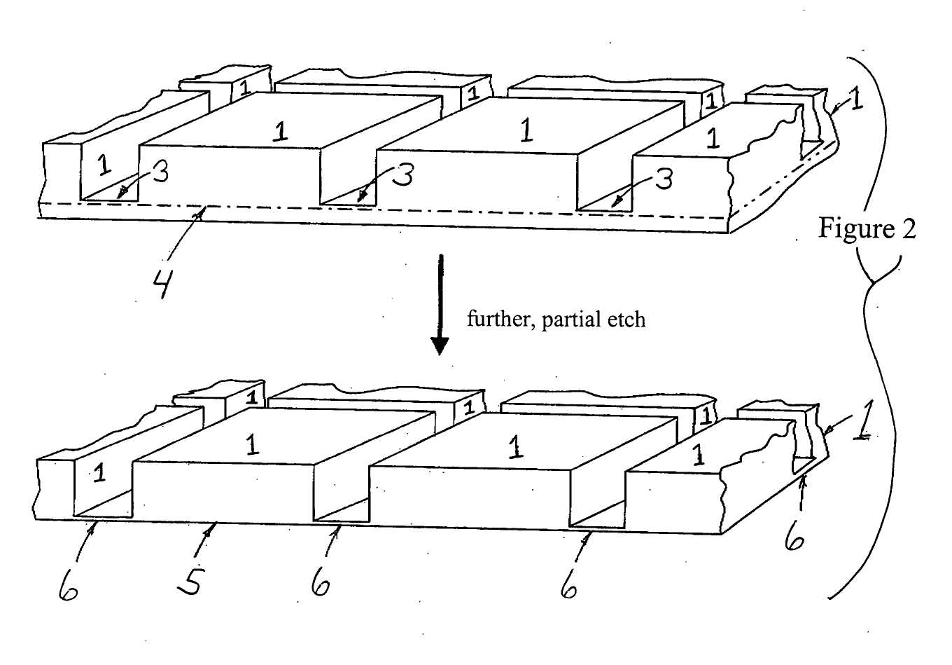

In FIG. 2 is depicted a schematic, perspective sequence of two (2) views illustrating one method according to the present invention of leaving planar, horizontal interconnecting webs 6 at the bottom of the wafer that hold the die together until they are later broken or taken apart. In the top view of the Figure, a wafer has been dry etched partially down to depth 3 just above the dashed line for depth 4. After bottom side polishing or etching, dashed line 4 becomes the exposed planar bottom side 5 in the bottom view of the Figure. The horizontal webs 6 remain so as to hold adjacent die 1 together. Thereby, subsequent process steps can be accomplished, in bulk, to the newly exposed bottom 5 of the die 1.

In an alternative embodiment of the present invention, no bottom side polishing or etching is performed. In this case, the troughs are dry etched to a depth such that the thin webs 6 are formed without removal of the bottom side material. The die 1 are then able to be broken or taken apart, as required, at a later time.

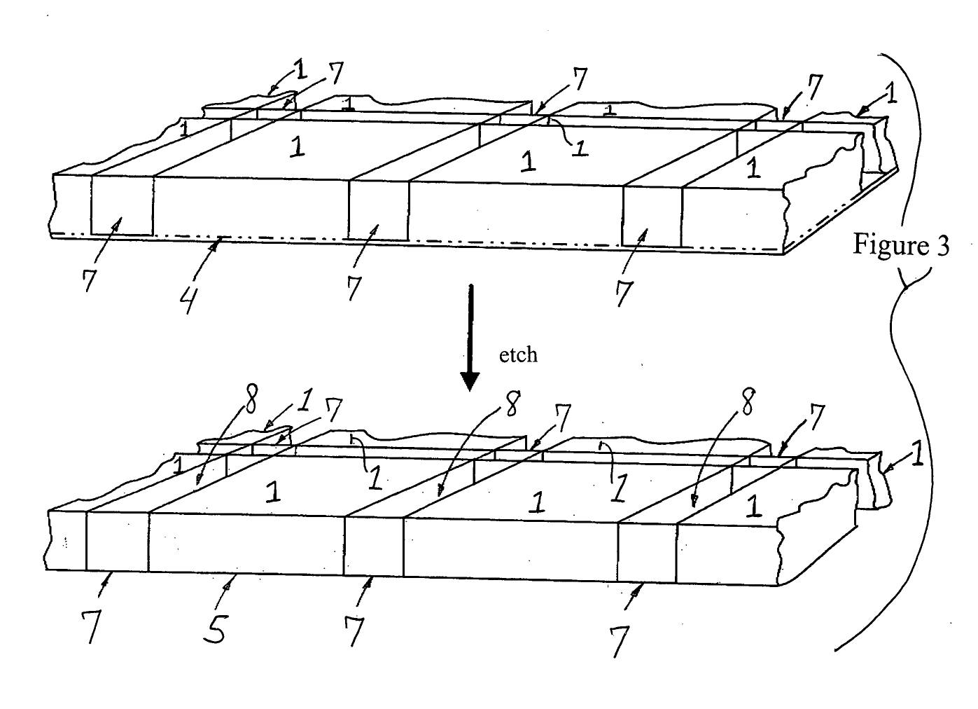

FIG. 3 is a schematic, perspective sequence of two (2) views of an alternate embodiment and method of the present invention, in which the die are connected by vertical interconnecting webs 7. Rather than the horizontal webs described above, these vertical webs are constructed by applying photo-patterning across their top sections prior to dry etching. Note that on the corners there are four vertical webs 7 connecting four die 1. As described in FIG. 2 above, the bottom side 5 can be removed at dashed line 4 to leave open troughs 8, webs 7 and die 1. In yet another alternate embodiment, no bottom side polishing or etching is performed. In this case, the troughs may be dry etched through. The die 1 depicted in FIG. 3 may also be broken or taken apart along the thin vertical webs 7 at a later time.

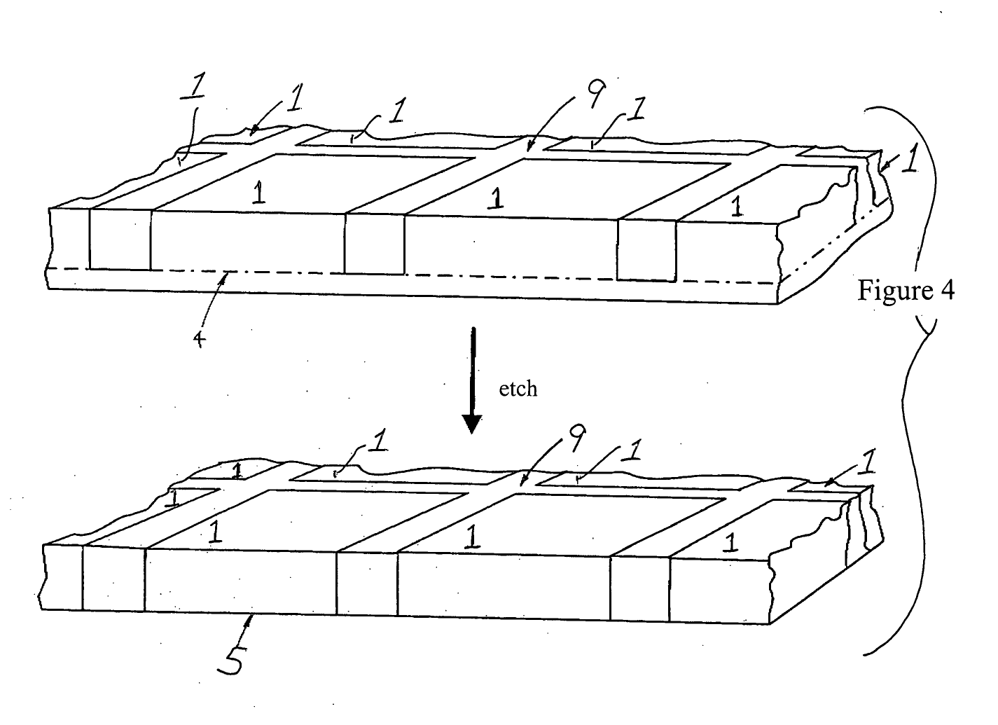

FIG. 4 is a schematic, perspective sequence of two (2) views of an alternate embodiment and method of the present invention depicting a method of using a filler material between individual die after a partial through-etch according to the method of FIG. 2. In the top view of FIG. 4, a wafer is first dry etched partially down to the depth of dashed line 4. Then a filling material 9, according to conventional techniques, is spun or deposited into the troughs to act as a binder between the die. After bottom side polishing or etching, dashed line 4 becomes the exposed planar bottom side 5 in the bottom view of the Figure. The filler 9 remains so as to hold the die 1 together. Thereby, subsequent process steps can be accomplished, in bulk, to the newly exposed bottom of the die 1, and the filler later removed by conventional techniques.

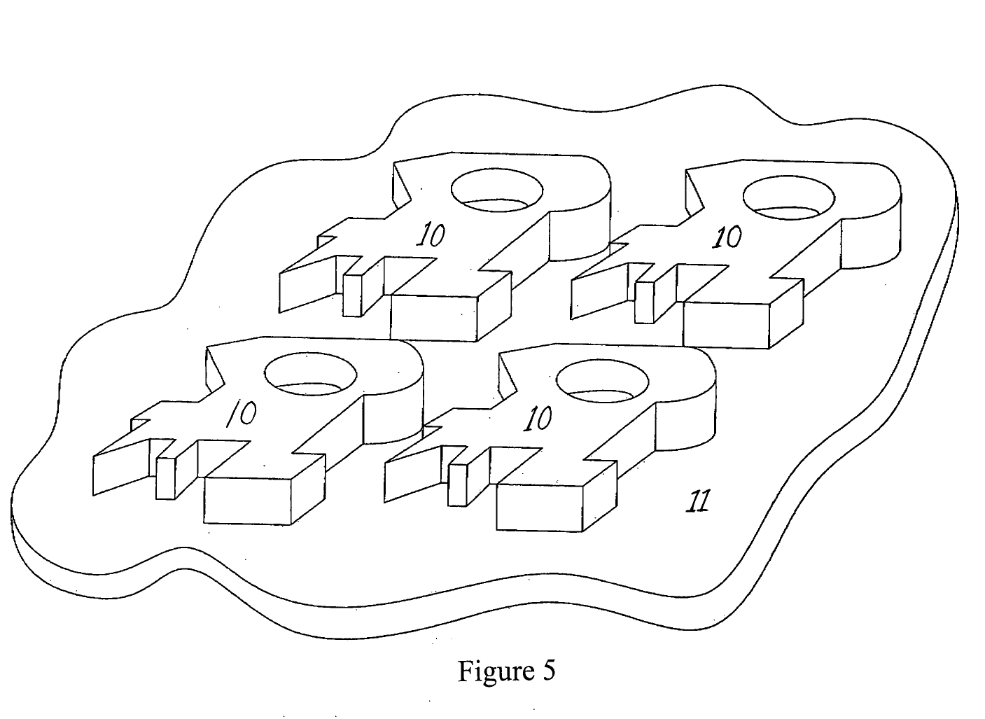

FIG. 5 is a schematic, perspective view of the present invention depicting odd-shaped die 10 that have already undergone partial dry etching to expose interconnectiong horizontal webs of their substrate 11. This depiction serves to show that micromachined or MEMS die can take odd forms, that can be dry etch separated in the same manner as described above with equal precision. In a similar manner to the description relating to FIG. 1, above, these die will also exhibit ultra-linear sidewalls and will have none of the problems associated with laser cutting or dicing. In a manner similar to the various embodiments described, these odd-shaped parts can also be connected by webs or fillers, and can be separated or released by partial trough formation and bottom side removal, or by complete through-etching. This allows bulk post-processing steps to be taken, and also allows for ease of subsequent separation, in the same manner as the methods described above.

In this invention, the dry-etch processes are the well-known Deep Reactive Ion Etching (DRIE) or Bosch etching processes, and their equivalents. The DRIE or Bosch etching processes are highly anisotropic, and create deep, vertical pits with nearly straight sides in materials such as silicon. The materials in which the semiconductor, micromachined or Micro-Electro-Mechanical System (MEMS) structures or devices are made according to this invention include uniform silicon, silicon carbide, quartz, germanium, germanium arsenide, etc., and their equivalents. By uniform, Applicant means the substrate is substantially homogenous, without insulator or etch-stop layers of other material.

Although this invention has been described above with reference to particular means, materials, and embodiments, it is to be understood that the invention is not limited to these disclosed particulars, but extends instead to all equivalents within scope of the following Claims.

We claim:

1. A method of dry-etch release of a die from a uniform substrate, except a silicone-on-insulator substrate, said substrate having a top surface and a thickness, the method comprising:
application of photo patterning to said top surface of the substrate to expose areas to be dry-etched; and,
dry-etching via the Bosch or deep reactive ion etch (DRIE) process completely
through said substrate thickness to release said die.

2. A method of dry-etch release of a die from a uniform substrate, except a silicone-on-insulator substrate, said substrate having a top surface and a thickness, the method comprising:
application of photo patterning to said top surface of the substrate to expose areas to be dry-etched; and,
dry etching via the Bosch or deep reactive ion etch (DRIE) process at least
partially through said substrate thickness to leave horizontal tabs or webs of the original substrate which are a fraction of the thickness of the original substrate and, later removing the horizontal tabs or webs to release the die.

3. A method of dry-etch release of a die from a uniform substrate, except a silicone-on-insulator substrate, said substrate having a top surface and a thickness, the method comprising:
application of photo patterning to said top surface of the substrate to expose areas to be dry-etched;
dry-etching via the Bosch or deep reactive ion etch (DRIE) process at least partially through said substrate thickness to leave vertical tabs or webs of the original substrate, and later removing the vertical tabs or webs to release the die.
